(19) United States
(12) Patent Application Publication
(10) Pub. No.: US 2011/0019125 A1
(43) Pub. Date: Jan. 27, 2011

(54) MOUNTED BOARD, MOUNTED BOARD SET, AND PANEL UNIT

(76) Inventors: Hiroki Nakahama, Osaka (JP); Kiyoshi Inada, Osaka (JP)

Correspondence Address: BIRCH STEWART KOLASCH & BIRCH, PO BOX 747, FALLS CHURCH, VA, 22040-0747, US

(21) Appl. No.: 12/933,159

(22) PCT Filed: Nov. 10, 2008
(86) PCT No.: PCT/JP2008/070383

§ 371 Date: Sep. 17, 2010

(30) Foreign Application Priority Data
Mar. 19, 2008 (JP) 2008-070671

(51) Int. Cl. G02F 1/1333; H05K 1/00; H05K 1/09

(52) U.S. Cl. 349/58; 174/250; 174/251

(57) ABSTRACT

Disclosed is a mounted board (11) comprising a feed wire (13) for supplying a current to a circuit element (21). In this mounted board (11), when a region of a mounting surface (12A) of the mounted board (11) overlapping the circuit element (21) is defined as a mounting area (MA), a reinforcing wire (17) overlapping a corner (PP) of the mounting area (MA) is formed on the mounting surface (12A).

### TECHNICAL FIELD

The present invention relates to a mounting board, a mounting board set that is a mounting board on which a circuit element and the like are mounted, and a panel unit that is a panel (a liquid crystal display panel or the like) provided with the mounting board set.

### BACKGROUND ART

Compact electronic devices of recent years including, for example, mobile tools such as a cellular phone often use a mounting board having flexibility. On such a mounting board, various circuit elements are mounted via an adhesive. However, when a load (stress) is applied on the mounting board on which the circuit elements are mounted (referred to also as a mounting board set), it becomes likely that the circuit elements peel off from the mounting board.

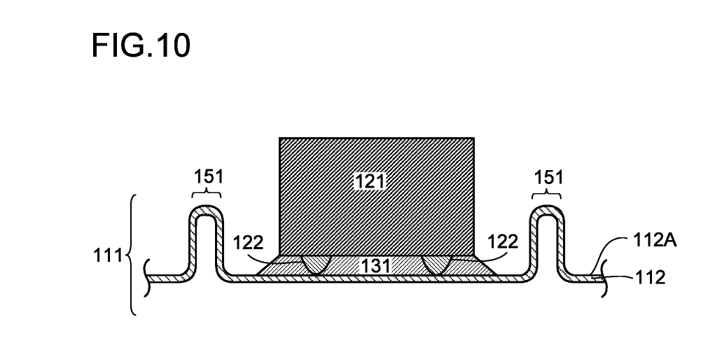

In order to avoid this, as shown in the cross-sectional view of FIG. 10, in the case of a mounting board 111 on which a circuit element 121 is mounted described in Patent Document 1, the mounting board 111 (more specifically, a main board 112 as a base of the mounting board 111) has been processed to be deformed plastically so as to surround the circuit element 121. More specifically, an inverted U-shaped wall portion 151 is formed in a partial area of the main board 112 surrounding the circuit element 121.

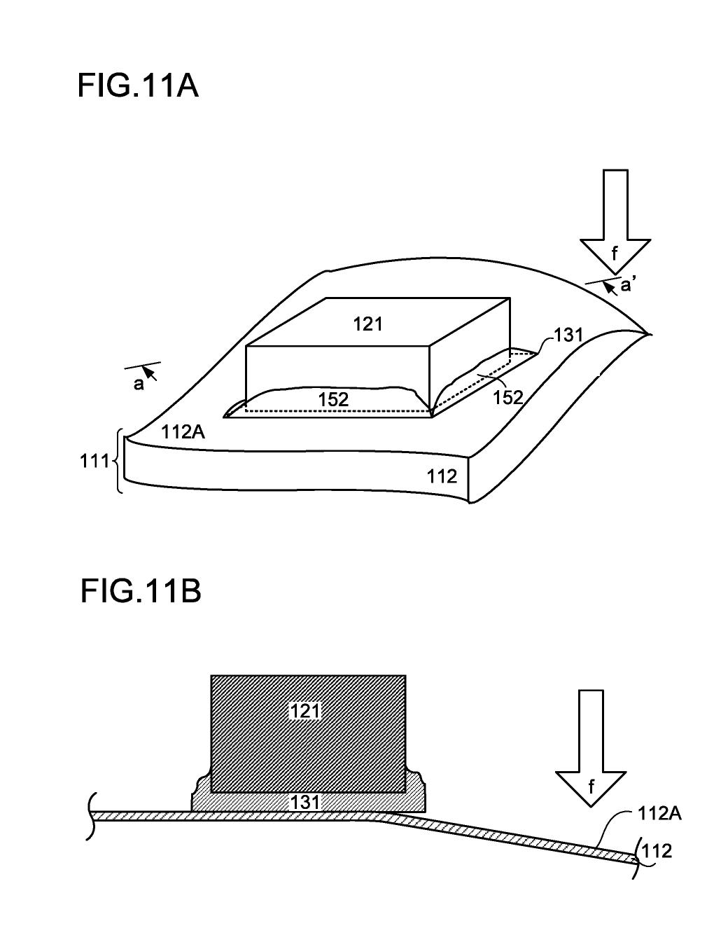

With this configuration, the peeling-off of the circuit element 121 that might occur on the mounting board 111 without the inverted U-shaped wall portion 151 as shown in FIG. 11A and FIG. 11B (a view in cross-section taken along line a-a′ of FIG. 11A) is prevented, i.e., for example, a corner of the circuit element 121 at which a fillet 152 of an adhesive 131 can hardly be formed is prevented from peeling off from the mounting board 111 (an arrow fin the figures represents a load).

### Patent Document 1: JP-A-2000-3935

### DISCLOSURE OF THE INVENTION

### Problems to be Solved by the Invention

However, the mounting board 111 described in Patent Document 1 requires, in its manufacturing, a process of subjecting the mounting board 111 to plastic deformation, and a material used therefor is limited to a plastically deformable material. For this reason, the manufacturing process of the mounting board 111 is burdensome, and highly versatile materials cannot be used for manufacturing the mounting board 111 (the material cost might lead to a cost increase of the mounting board 111).

Furthermore, although not shown in FIG. 10, a bump 122 is connected to wiring (not shown) included in the mounting board 111, and the wiring is preferably covered with a solder resist film However, the presence of the inverted U-shaped wall portion 151 on a mounting surface 112A of the mounting board 111 might cause the peeling-off and rupture of the solder resist film.

The present invention has been made in view of the above-described circumstances. An object of the present invention is to provide a mounting board of a simple structure that prevents a circuit element, when mounted on the mounting board, from peeling off from the mounting board, a mounting board set that is completed by mounting the circuit element on the mounting board, and a panel set that is obtained by linking the mounting board set to a liquid crystal display panel.

### MEANS FOR SOLVING THE PROBLEM

In a mounting board including feed wiring for supplying a circuit element with an electric current, where an area on a mounting surface of the mounting board, which overlaps the circuit element that is mounted, is defined as a mounting area, reinforcing wiring that overlaps a corner of the mounting area is formed on at least one of the mounting surface and a non-mounting surface on the back side of the mounting surface.

Normally, when a circuit element is mounted on the mounting board, a corner of the circuit element overlaps a corner of the mounting area. Therefore, if the mounting area is warped in the vicinity of the corner thereof, such warping might cause the corner of the circuit element to peel off from the mounting board.

However, in the case where the reinforcing wiring is positioned so as to overlap the corner of the mounting area, the rigidity of the mounting area in the vicinity of the corner thereof increases to prevent the warping. Thus, the mounting board configured as above prevents, even when a circuit element is mounted thereon, a corner of the circuit element from peeling off from the mounting board.

Preferably, the reinforcing wiring extends out from the corner of the mounting area to the outside of the mounting area. According to this configuration, the mounting board is allowed to be warped at a portion outside the mounting area, in which the reinforcing wiring is not present. This makes it sure that the mounting area is not warped in the vicinity of a corner thereof and thus even when a circuit element is mounted on the mounting board, a corner of the circuit element is prevented from peeling off from the mounting board.

Furthermore, preferably, an imaginary bisector line is defined by extending a line bisecting an angle at the corner of the mounting area, and the mounting board satisfies a conditional expression (1) below:

0<L/D≦30 (1)

where

L: a maximum length that extends from one end of the imaginary bisector line, which overlaps the corner of the mounting area, toward the outside of the mounting area while overlapping the imaginary bisector line and reaches an edge of the reinforcing wiring; and

D: a thickness of the reinforcing wiring.

One factor that might cause a corner of a circuit element, when mounted on the mounting board, to peel from the mounting board is, for example, a load applied on a corner of the mounting area. For this reason, the reinforcing wiring may be formed so that such a load is not transmitted to the corner of the mounting area. To this end, it is necessary that the reinforcing wiring withstand a load with respect to the mounting board that is applied on the corner of the mounting area and transmitted along the imaginary bisector line. The conditional expression (1) thus should be satisfied so that the reinforcing wiring has rigidity of a given degree or higher. That is, the reinforcing wiring should not be too long in order to have rigidity of a given degree or higher.

Meanwhile, normally, on the mounting surface, it is necessary that an area for mounting a circuit element (mounting area) be secured with precision, and therefore, for example, a solder resist film (first protective film) is formed by photolithography that allows high-precision film formation. On the other hand, on the non-mounting surface, since there is no need for film formation precision as high as required for the mounting surface, for example, a coverlay film (second protective film) is formed that is more excellent in insulation property than a solder resist film and has high rigidity.

In this regard, a protective film that covers at least the feed wiring on the mounting surface is defined as a first protective film (solder resist film, etc.), a protective film that covers at least the feed wiring on the non-mounting surface is defined as a second protective film (coverlay film, etc.), and an imaginary bisector line is defined by extending a line bisecting an angle at the corner of the mounting area. In this case, preferably, in the mounting board, an area defined by a minimum distance between one end of the reinforcing wiring, which overlaps the imaginary bisector line, and one end of the second protective film, which overlaps the imaginary bisector line, is composed only of a main board as a base of the mounting board and the first protective film.

According to this configuration, under a load with respect to the mounting board that is applied on a corner of the mounting area and transmitted along the imaginary bisector line, a partial area composed only of the main board as the base of the mounting board and the first protective film that have relatively low rigidity (high flexibility and a high warping property), i.e. a portion of the mounting board including a minimum distance between one end of the reinforcing wiring, which overlaps the imaginary bisector line, and one end of the second protective film, which overlaps the imaginary bisector line, is allowed to be warped. As a result, the mounting area is not warped in the vicinity of a corner thereof, and thus even when a circuit element is mounted on the mounting board, a corner of the circuit element is prevented from peeling off from the mounting board.

Furthermore, when the reinforcing wiring extends out from the corner of the mounting area to the inside of the mounting area, the mounting board can be configured also to prevent an inner portion of the mounting area thereof from being warped.

Preferably, particularly when one end in the mounting area, which overlaps a bump of the circuit element, is defined as an electrode superimposition point, a group of a plurality of the electrode superimposition points is defined as an electrode superimposition point group, an imaginary bisector line is defined by extending a line bisecting an angle at the corner of the mounting area, and a line connecting, among the outermost ones of the electrode superimposition points in the electrode superimposition point group, ones that sandwich the imaginary bisector line therebetween and are adjacent to each other at a minimum distance is defined as a boundary line, the reinforcing wiring extends out from the corner of the mounting area toward the inside of the mounting area across the boundary line.

According to this configuration, the reinforcing wiring extends to the side of the center of the mounting area. This makes it sure that the warping of an inner portion of the mounting area on the mounting board is prevented by the presence of the reinforcing wiring.

The reinforcing wiring may function also as the feed wiring. According to this configuration, even in the case of a circuit element having a relatively large number of bumps arranged at a small pitch, the area occupied by the reinforcing wiring is increased.

Furthermore, preferably, an adhesive is interposed between the circuit element and the mounting area. According to this configuration, the mounting area is linked to a circuit element with high rigidity via an adhesive. This prevents the warping of the mounting area on the mounting board.

It can be said that the scope of the present invention also includes a mounting board set that includes a mounting board having the above-described configuration and a circuit element mounted on the mounting board.

Furthermore, in the case of a mounting board set in which the bump included in the circuit element is connected to the feed wiring linked to the electrode superimposition point, the warping of part of the feed wiring connected to the circuit element is prevented by the presence of the reinforcing wiring. This prevents the peeling-off between a bump of a circuit element and the feeding wiring.

It can be said that the scope of the present invention also includes a panel unit that includes a mounting board set having the above-described configuration and a liquid crystal display panel linked to the mounting board set.

### ADVANTAGES OF THE INVENTION

According to the mounting board of the present invention, even when a circuit element is mounted on the mounting board, the warping of a partial area of the mounting board in the vicinity of a corner of the circuit element is prevented by the presence of the reinforcing wiring. Thus, the corner of the circuit element is prevented from peeling off from the mounting board.

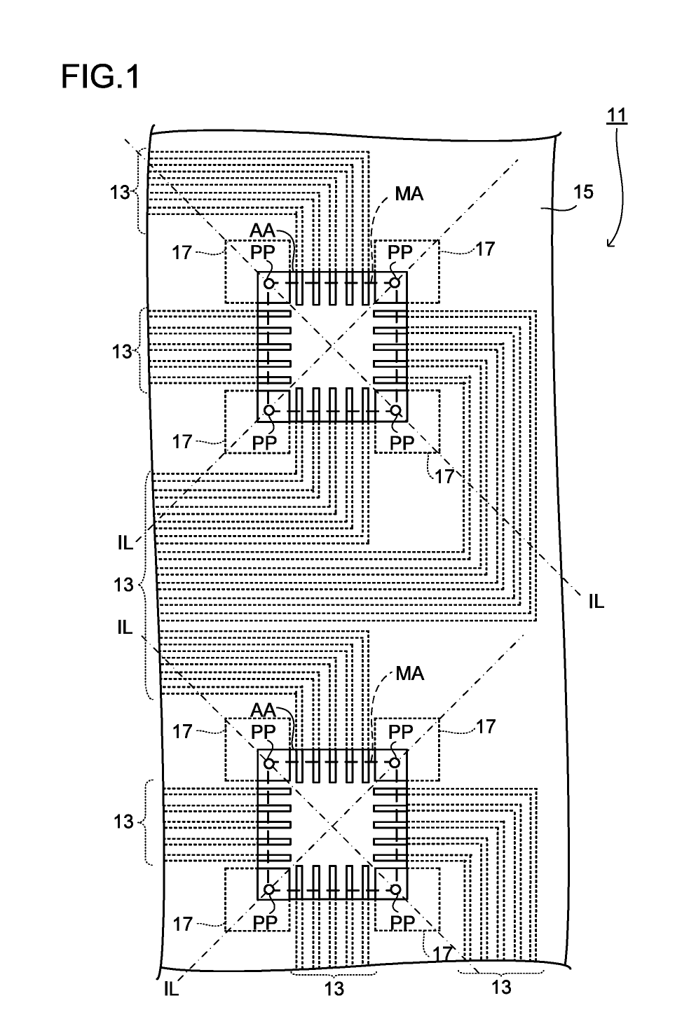

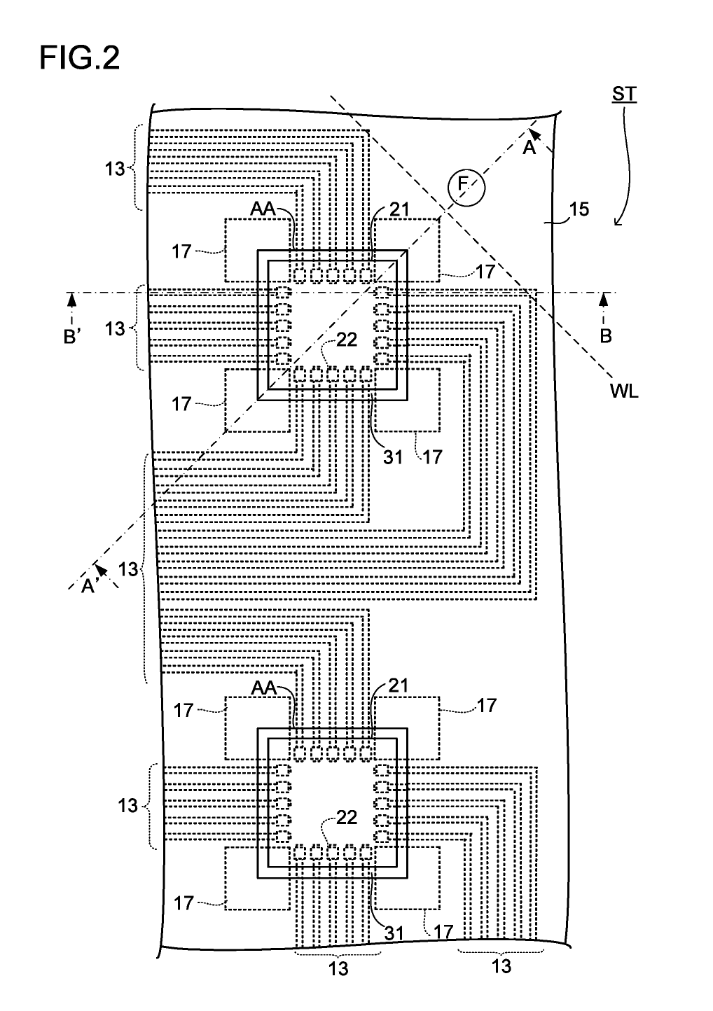

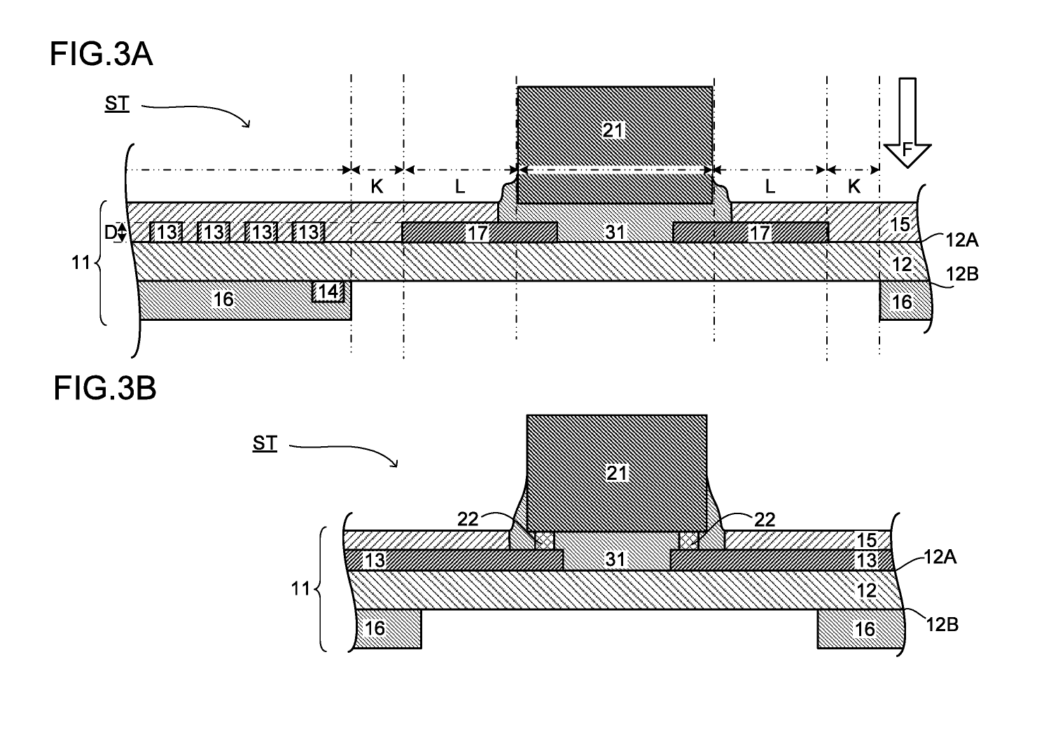

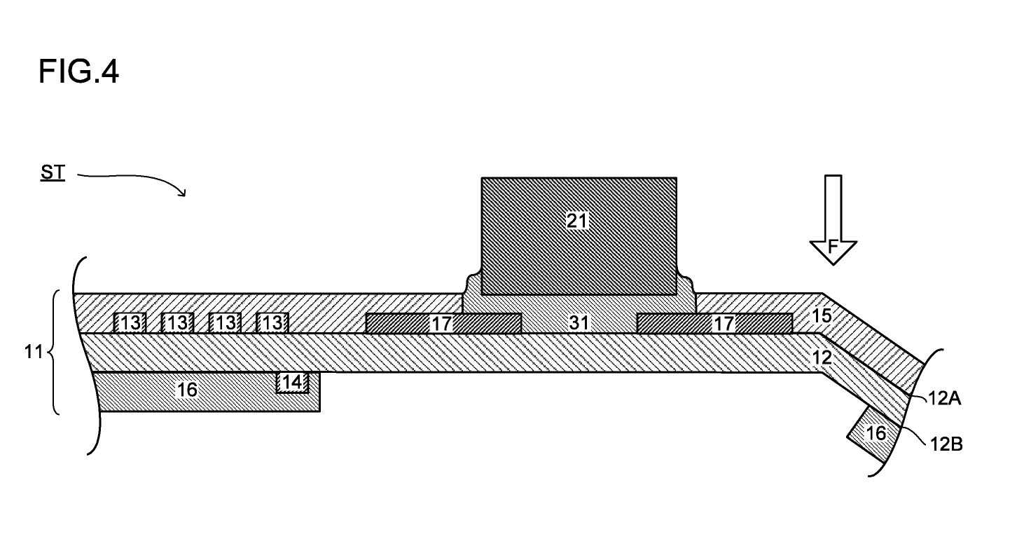

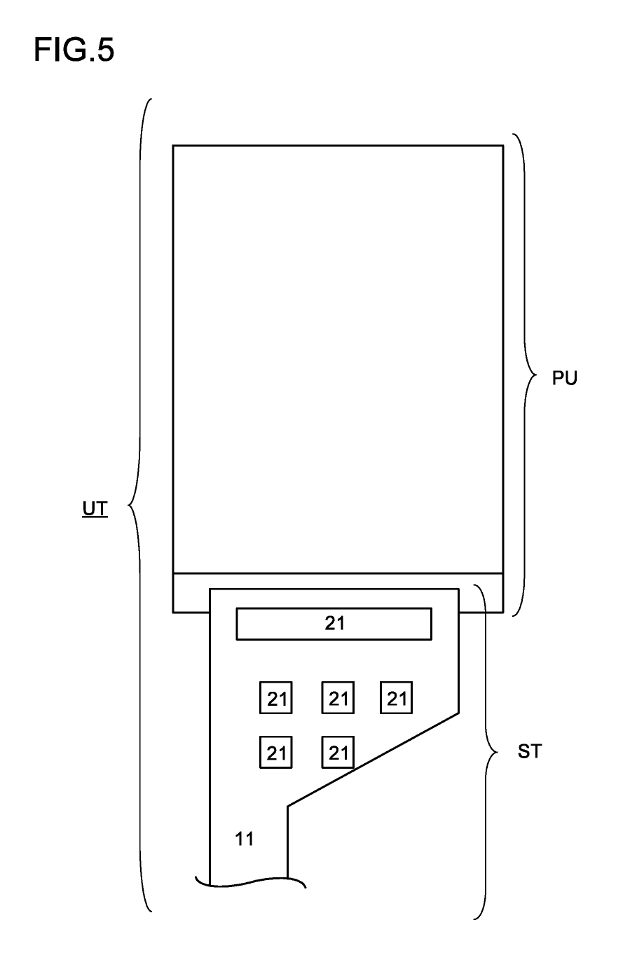

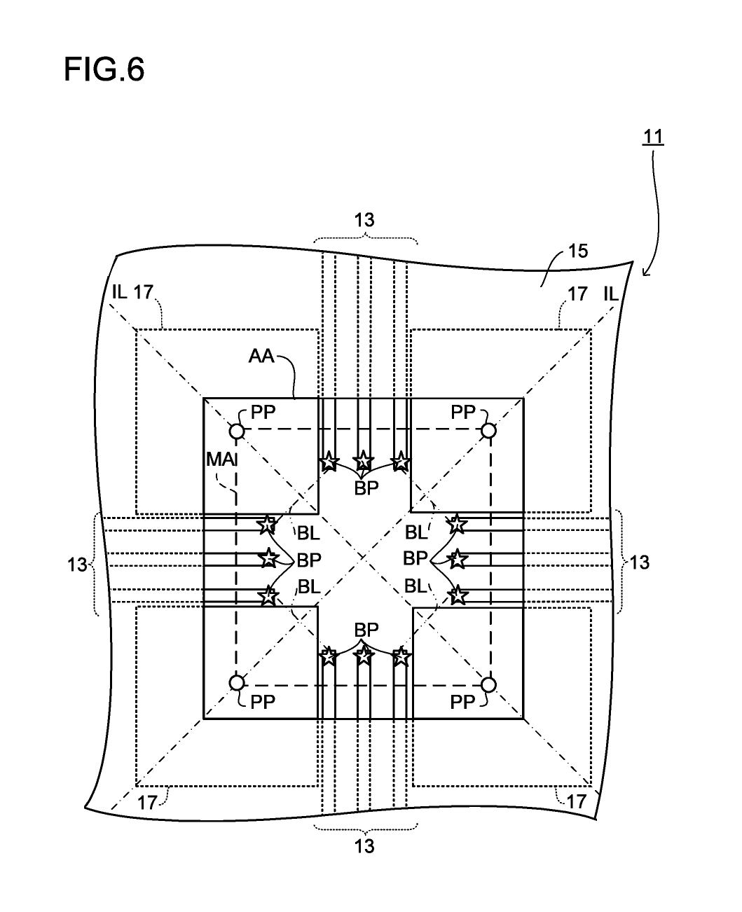

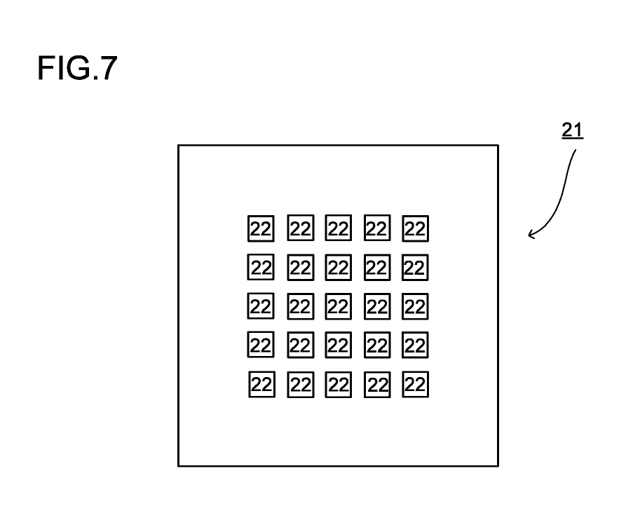

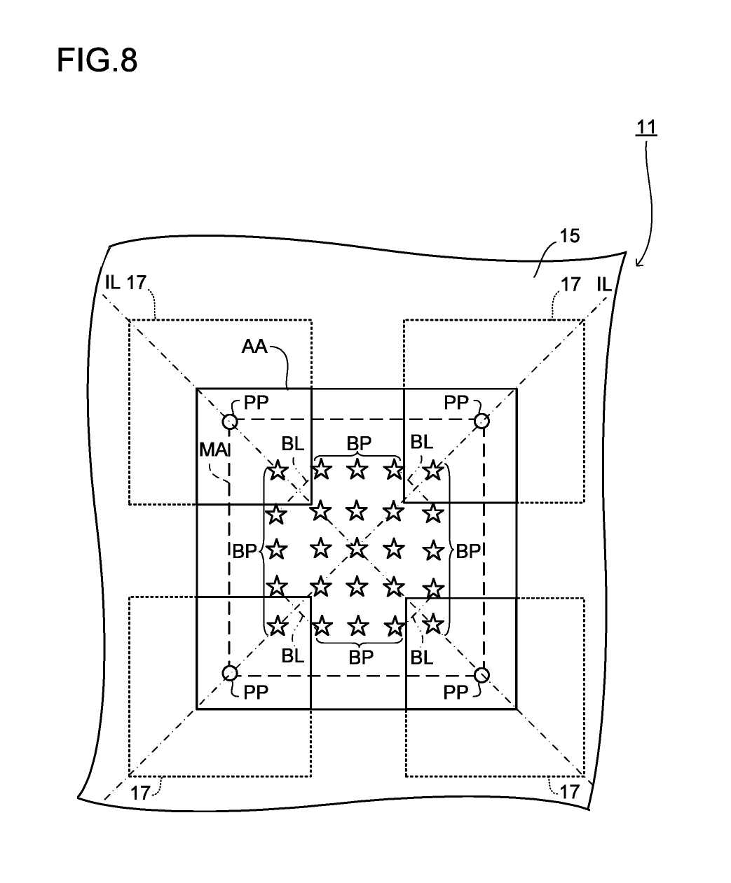

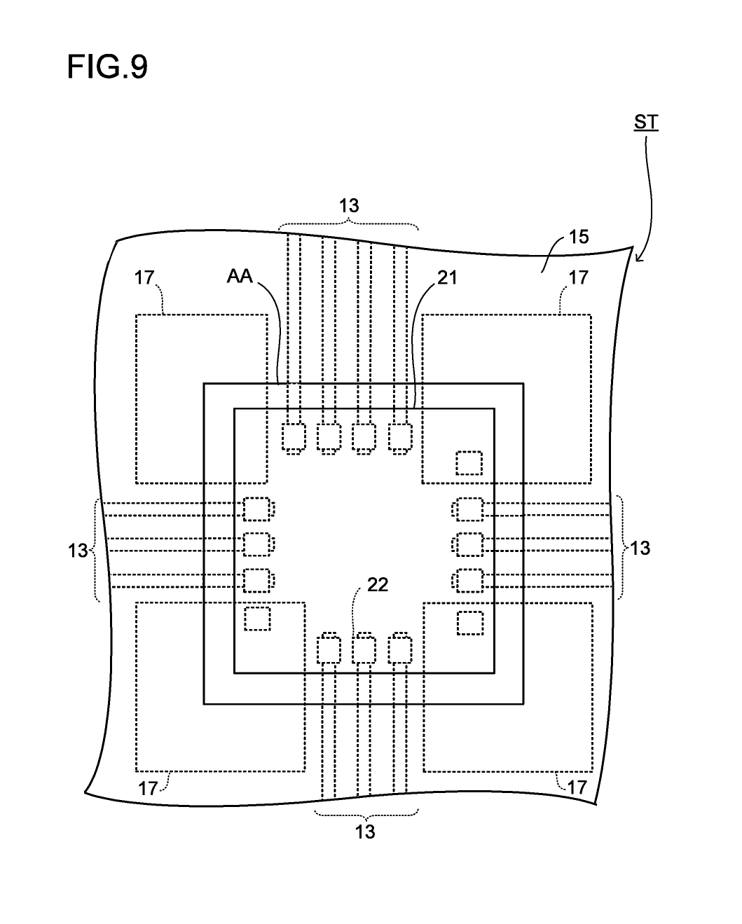

### BRIEF DESCRIPTION OF DRAWINGS

[FIG. 1] A plan view of a mounting board as seen from a front surface (mounting surface).

[FIG. 2] A plan view of a mounting board set as seen from the mounting surface.

[FIG. 3A] A view in cross-section taken along line A-A′ of FIG. 2.

[FIG. 3B] A view in cross-section taken along line B-B′ of FIG. 2.

[FIG. 4] A cross-sectional view showing a state of the mounting board being warped.

[FIG. 5] A plan view of a panel unit.

[FIG. 6] A plan view of a mounting board different from the mounting board shown in FIG. 1.

[FIG. 7] A plan view showing bumps of a circuit element.

[FIG. 8] A plan view of a mounting board different from the mounting boards shown in FIGS. 1 and 6, respectively.

[FIG. 9] A plan view showing a mounting board set different from the mounting board set shown in FIG. 2.

[FIG. 10] A cross-sectional view of a mounting board set according to the conventional technique.

[FIG. 11A] A perspective view of a mounting board set according to the conventional technique different from the mounting board set shown in FIG. 10.

[FIG. 11B] A view in cross-section taken along line a-a′ of FIG. 11A.

### LIST OF REFERENCE SYMBOLS

11 Mounting board

12 Main board

13 Feed wiring

14 Interconnecting wiring (feed wiring)

15 Solder resist film (first protective film)

16 Coverlay film (second protective film)

17 Reinforcing wiring

MA Mounting area

PP Corner of mounting area

AA Aperture area

IL Imaginary Bisector line

BL Boundary line

WL Warping line

21 Circuit element

22 Bump

31 Adhesive

PU Liquid crystal display panel

ST Mounting board set

UT Panel unit

BEST MODE FOR CARRYING OUT THE INVENTION

### Embodiment 1

The following describes an embodiment with reference to the appended drawings. For the sake of convenience, hatching, reference symbols of members, and the like may be omitted in some of the drawings, in which case reference should be made to the other drawings.

FIG. 5 is a plan view showing a liquid crystal display panel PU to be incorporated into an electronic device such as a cellular phone and a mounting board set ST linked to the liquid crystal display panel PU, and FIG. 2 is an enlarged plan view of the mounting board set ST (a unit as a combination of the liquid crystal display panel PU and the mounting board set ST is referred to as a panel unit UT). Furthermore, FIGS. 3A and 3B are a view in cross-section taken along line A-A′ of FIG. 2 and a view in cross-section taken along line B-B′ of FIG. 2, respectively (the line A-A′ is used also as an imaginary bisector line IL that will be described later).

The mounting board set ST shown in these figures includes a circuit element 21 of various types and a mounting board 11 on which the circuit element 21 is mounted (the circuit element 21 is mounted using an adhesive 31 such as an ACF (anisotropic conductive film) or a NCF (non-conductive film)).

Herein, the mounting board 11 will be described in detail with reference to the aforementioned drawings and also to FIG. 1 that is a plan view of the mounting board 11 excluding the circuit element 21. The mounting board 11 includes a main board 12, feed wiring 13, interconnecting wiring 14, a solder resist film (first protective film) 15, a coverlay film (second protective film) 16, and reinforcing wiring 17.

The main board 12 is a member as a base of the mounting board 11 and has flexibility. The mounting board 11 including the main board 12 thus is referred also to as a FPC (flexible printed circuit) board. Examples of a material for the main board 12 include polyimide resin and PET (polyethylene terephthalate).

The feed wiring 13 is linked to, for example, a bump (protrusion electrode) 22 included in the circuit element 21 and supplies the circuit element 21 with an electric current from a power supply that is not shown. Therefore, as shown in FIG. 3B, the bump 22 is connected to the feed wiring 13. It is sufficient that the feed wiring 13 is formed on at least one of a front surface (mounting surface) 12A and a back surface (non-mounting surface) 12B of the main board 12.

As shown in, for example, FIG. 3A, the interconnecting wiring 14 is wiring formed on the back surface 12B of the main board 12 and connects groups of conductors constituting the feed wiring 13. The interconnecting wiring 14 performs the same function as that of the feed wiring 13 in the sense that it supplies the circuit element 21 with an electric current, and therefore can be regarded also as a type of the feed wiring 13.

The solder resist film 15 is a resin film formed by photolithography and covers the front surface 12A of the main board 12 thereby to protect the feed wiring 13 (more specifically, the solder resist film 15 covers at least the feed wiring 13 on the mounting surface 12A).

The solder resist film 15 does not entirely cover the front surface 12A of the main board 12 and, specifically, as shown in FIG. 1, does not cover a partial area (aperture area AA) on the front surface 12A of the main board 12, which is to be used for mounting the circuit element 21. For this reason, photolithography that allows patterning with precision is used so as to secure such an area as described above, which is not to be covered by the solder resist film 15.

The coverlay film 16 is a film that covers wiring (such as the feed wiring 13 and the interconnecting wiring 14) formed on the back surface 12B of the main board 12 (more specifically, the coverlay film 16 covers at least the feed wiring 13 such as the interconnecting wiring 14 on the non-mounting surface 12B). Therefore, the coverlay film 16 is not present in an area on the back surface 12B of the main board 12, in which wiring is not formed (for example, an area on the back surface 12B immediately below the circuit element 21). The coverlay film 16, although it is inferior in terms of patterning precision to the solder resist film 15 formed by photolithography, has an insulation property and rigidity higher than those of the solder resist film 15.

The reinforcing wiring 17 prevents warping of a partial area of the mounting board 11 and determines which portion of the mounting board 11 is allowed to be warped. As one example, as shown in FIG. 1, the reinforcing wiring 17 overlaps a corner PP of a mounting area MA that is an area on the front surface 12A of the main board 12, which overlaps the circuit element 21. More specifically, the reinforcing wiring 17 extends out from the corner PP of the mounting area MA to the outside of the mounting area MA.

Consequently, on the front surface 12A of the main board 12, part of the reinforcing wiring 17 is covered by the solder resist film 15, while the remaining part of the reinforcing wiring 17 is not covered by the solder resist film 15 but extends out into the area (aperture area) AA that is to be used for mounting the circuit element 21.

With the reinforcing wiring 17 configured as above, as shown in, for example, FIGS. 2 and 3A, when a load F is applied on the mounting board 11, the mounting board 11 tends to be warped along a line (warping line) WL. When warped, the mounting board 11 is brought to the state shown in the cross-sectional view of FIG. 4.

More specifically, as shown in FIG. 4, the mounting board 11 is warped not in the vicinity of a corner of the circuit element 21 but on the side deviating from the mounting area MA with respect to the reinforcing wiring 17. This is because the reinforcing wiring 17 is positioned so as to overlap the corner of the circuit element 21, thereby allowing a portion of the mounting board 11 in the vicinity of the corner of the circuit element 21 to withstand the load F.

In other words, the reinforcing wiring 17 allows a partial area of the mounting board 11 to withstand the load F and thus defines another partial area of the mounting board 11 on the side deviating from the mounting area MA with respect to itself as an area allowed to be warped under the load F.

In the above-described case where the partial area of the mounting board 11 apart from the vicinity of a corner of the circuit element 21 is allowed to be warped, the corner of the circuit element 21 is prevented from peeling off from the mounting board 11 due to the load F. Preventing such peeling-off prevents the occurrence of defects in performance of the circuit element 21 (for example, contact failure) and thus improves the quality of the mounting board set ST.

The contact failure of the circuit element 21 occurring in the mounting board set ST results mainly from the peeling-off of a corner of the circuit element 21 from the mounting board 11 (the peeling-off of a corner of the circuit element 21 from the mounting board 11 is caused because of the fact that a fillet of the adhesive 31 hardly can be formed at the corner of the circuit element 21). Therefore, preventing the peeling-off of a corner of the circuit element 21 from the mounting board 11 reduces the occurrence of in-process defects, thereby allowing longer usage life of the high quality mounting board set ST.

Incidentally, the shape of the reinforcing wiring 17 is not particularly limited. The reinforcing wiring 17 may have a quadrangular shape as shown in FIG. 1 or any of other shapes including a polygonal shape, a circular shape, a linear shape, a net-like shape, and a circuitous shape. It is preferable, however, that the mounting board 11 satisfies an after-mentioned conditional expression (1).

More specifically, preferably, an imaginary bisector line IL (see FIG. 1) is defined by extending a line bisecting an angle at the corner PP of the mounting area MA, and the following conditional expression (1) is satisfied (see also FIG. 3A). By the conditional expression (1), a maximum length that extends from one end of the reinforcing wiring 17, which overlaps the corner PP of the mounting area MA, toward the outside of the mounting area MA while overlapping the imaginary bisector line IL and reaches an edge of the reinforcing wiring 17 is normalized with respect to the thickness of the reinforcing wiring 17. In the figure, “L” represents only a distance value denoted with a sign “+”, which will be described below.

0<L/D≦30 (1)

where

L: a maximum length that extends from one end of the reinforcing wiring 17, which overlaps the corner PP of the mounting area MA, toward the outside of the mounting area MA while overlapping the imaginary bisector line IL and reaches an edge of the reinforcing wiring 17 (in this case, L is denoted with a sign “+” when extending toward the outside of the mounting area MA while overlapping the imaginary bisector line IL, and with a sign “−” when extending toward the inside of the mounting area MA while overlapping the imaginary bisector line IL); and

D: a thickness of the reinforcing wiring 17.

In the case where the value of L/D (aspect ratio) is not more than a lowest value, for example, the reinforcing wiring 17 overlaps only an inner portion of the mounting area MA. Because of this, when the load F is applied on the mounting board 11, the mounting board 11 is not warped along the warping line WL (see FIG. 2) but could be warped in the vicinity of a corner of the circuit element 21. As a result, the corner of the circuit element 21 might peel off from the mounting board 11.

Meanwhile, in the case where the value of L/D exceeds an upper value, a portion of the reinforcing wiring 17 that overlaps the imaginary bisector line IL becomes excessively long, making it likely that the reinforcing wiring 17 itself is bent. Because of this, when the load F is applied on the mounting board 11, not only the mounting board 11 but also the reinforcing wiring 17 might be warped. This might cause one end of the reinforcing wiring 17, which overlaps a corner of the circuit element 21 (the corner PP of the mounting area MA), also to be warped. Such warping of the reinforcing wiring 17 causes the mounting board 11 to be warped in the vicinity of the corner of the circuit element 21, so that the corner of the circuit element 21 might peel off from the mounting board 11.

Thus, when the value of L/D falls within a value range given by the conditional expression (1), the mounting board 11 is not warped in the vicinity of a corner of the circuit element 21, and thus the corner of the circuit element 21 is prevented from peeling off from the mounting board 11. This prevents the occurrence of defects in performance of the circuit element 21 and thus improves the quality of the mounting board set ST.

Preferably, a conditional expression (1a) determining conditions below among the conditions determined by the conditional expression (1) is satisfied.

0<L/D≦20 (1a)

Furthermore, preferably, as shown in FIG. 3A, an area defined by a minimum distance K between one end of the reinforcing wiring 17, which overlaps the imaginary bisector line IL, and one end of the coverlay film 16, which overlaps the imaginary bisector line IL, is composed only of the main board 12 and the solder resist film 15.

According to this configuration, the area defined by the minimum distance K including two members having relatively low rigidity (main board 12, solder resist film 15) is more likely to be warped compared with an area defined by the distance L including the reinforcing wiring 17 having relatively high rigidity. Therefore, when the load F is applied on the mounting board 11, the area of the mounting board 11 defined by the distance L is not warped, while the area of the mounting board 11 defined by the distance K is warped. This makes it sure that a corner of the circuit element 21 is prevented from peeling off from the mounting board 11.

With respect to partial areas of the mounting board 11 shown in FIG. 3A, i.e. a partial area of the mounting board 11 including the distance K, a partial area of the mounting board 11 including the distance L, a partial area of the mounting board 11 overlapping the coverlay film 16, and a partial area of the mounting board 11 overlapping the circuit element 21, the likelihood that these partial areas might be warped decreases in this order.

Meanwhile, the functions of the reinforcing wiring 17 are not limited to preventing the peeling-off of a corner of the circuit element 21 from the mounting board 11. For example, in the case where the circuit element 21 is thin and thus is easily bendable, the reinforcing wiring 17 prevents the warping of an inner portion of the mounting area MA on the mounting board 11, thereby making it sure that peeling-off between the bump 22 of the circuit element 21 and the feed wiring 13 is prevented.

The above-described prevention could be achieved by the following configuration. That is, the reinforcing wiring 17 extends out from the corner PP of the mounting area MA to the inside of the mounting area MA.

According to this configuration, the reinforcing wiring 17 extending out to the inside of the mounting area MA extends toward the center of the mounting area MA. Thus, the warping of an inner portion of the mounting area MA on the mounting board 11 is prevented by the presence of the reinforcing wiring 17.

In addition, the following configuration is more preferable. That is, as shown in FIG. 6, one end of the feed wiring 13 in the mounting area MA, which overlaps the bump 22 of the circuit element 21, is defined as an electrode superimposition point BP. Further, a line connecting ones of the electrode superimposition points BP, which sandwich the imaginary bisector line IL therebetween and are adjacent to each other at a minimum distance, is defined as a boundary line BL. Under these definitions, the reinforcing wiring 17 extends out from the corner PP of the mounting area MA toward the inside of the mounting area MA across the boundary line BL.

According to this configuration, the reinforcing wiring 17 extends further to the side of the center of the mounting area MA beyond a tip end of the feed wiring 13. Thus, the warping of an inner portion of the mounting area MA on the mounting board 11 further is prevented by the presence of the reinforcing wiring 17.

The bumps 22 included in the circuit element 21 may be arranged in a lattice form as shown in FIG. 7. The electrode superimposition points BP in the mounting area MA, which correspond to the circuit element 21 of such a type, are arranged in a lattice form as shown in FIG. 8. In the case of this arrangement, the boundary line BL can be said also to be a line connecting, among the outermost ones of a group of the electrode superimposition points BP in a lattice form (electrode superimposition point group), ones that sandwich the imaginary bisector line IL therebetween and are adjacent to each other at a minimum distance.

Needless to say, also in the case shown in each of FIGS. 1 and 6 where a group of the electrode superimposition points BP are not arranged in a lattice form, the boundary line BL is a line connecting, among the outermost ones of the group of the electrode superimposition points BP, ones that sandwich the imaginary bisector line IL therebetween and are adjacent to each other at a minimum distance.

In summary, the configurations shown in FIGS. 1, 6 and 8 can be described also as follows. That is, a group of a plurality of the electrode superimposition points BP is defined as the electrode superimposition point group, and the reinforcing wiring 17 extends out from the corner PP of the mounting area MA so as to overlap the boundary line BL connecting, among the outermost ones of the group of the electrode superimposition points BP, ones that sandwich the imaginary bisector line IL therebetween and are adjacent to each other at a minimum distance. This makes it sure that the warping of an inner portion of the mounting area MA on the mounting board 11 is prevented by the presence of the reinforcing wiring 17.

Furthermore, preferably, while overlapping the boundary line BL, the reinforcing wiring 17 allows a corner of itself to overlap the imaginary bisector line IL. This makes it sure that the warping of an inner portion of the mounting area MA in the vicinity of the corner of the circuit element 21 is prevented by the presence of the reinforcing wiring 17.

### Other Embodiments

The present invention is not limited to the aforementioned embodiment and can be embodied in various forms without departing from the spirit of the invention.

For example, although in each of the previously described configurations, the reinforcing wiring 17 is formed on the mounting surface 12A of the mounting board 11, there is no limitation thereto. That is, the reinforcing wiring 17 may be formed on the non-mounting surface 12B of the mounting board 11.

The point is that, when the circuit element 21 is mounted on the mounting board 11, as long as the reinforcing wiring 17 is positioned so as to overlap a corner of the circuit element 21, it does not matter whether the reinforcing wiring 17 is provided on the mounting surface 12A or the non-mounting surface 12B of the mounting board 11. In the foregoing discussion, the term “overlap” is used to explain a state of various members overlapping each other in the thickness direction of the main board 12.

Furthermore, as shown in FIG. 9, the bump 22 of the circuit element 21 may be linked to the reinforcing wiring 17. That is, the reinforcing wiring 17 may perform the same function as that of the feed wiring 13 (the point is that the reinforcing wiring 17 may function also as the feed wiring 13).

This configuration not only prevents the peeling-off of the circuit element 21 from the mounting board 11 but also increases the area occupied by the reinforcing wiring 17 even in the case where the bumps 22 (electrode superimposition points BP) of the circuit element 21 are arranged at a small pitch. For example, in the case where, as shown in FIG. 8, the electrode superimposition points BP are arranged densely in the mounting area MA, it can be said that the reinforcing wiring 17 functioning also as the feed wiring 13 is advantageous.

Furthermore, preferably, as shown in FIGS. 2 to 4, the adhesive 31 is interposed between the circuit element 21 and the mounting area MA. According to this configuration, the mounting area MA is linked to the circuit element 21 having relatively high rigidity via the adhesive 31. This prevents the warping of the mounting area MA on the mounting board 11.

Particularly in the case where the reinforcing wiring 17 extends to the inside of the mounting area MA, the mounting area MA is linked to the circuit element 21 and the reinforcing wiring 17 that have relatively high rigidity via the adhesive 31. The point is that, on the mounting area MA, the reinforcing wiring 17, the adhesive 31, and the circuit element 21 are stacked in this order, forming a four-layer structure composed of the mounting area MA, the reinforcing wiring 17, the adhesive 31, and the circuit element 21. Thus, the mounting area MA now is a component of the multilayer structure and therefore is not warped even when the load F is applied on the mounting board 11.

Although FIG. 5 shows the liquid crystal display panel PU as a panel, there is no limitation thereto. For example, as a panel, an organic EL (electroluminescence) panel and a plasma panel also may be used.

1. A mounting board comprising feed wiring for supplying a circuit element with an electric current,
wherein
where an area on a mounting surface of the mounting board, which overlaps the circuit element that is mounted, is defined as a mounting area,
reinforcing wiring that overlaps a corner of the mounting area is formed on at least one of the mounting surface and a non-mounting surface on a back side of the mounting surface.

2. The mounting board according to claim 1, wherein
the reinforcing wiring extends out from the corner of the mounting area to an outside of the mounting area.

3. The mounting board according to claim 2, wherein
an imaginary bisector line is defined by extending a line bisecting an angle at the corner of the mounting area, and
a conditional expression (1) below is satisfied:
0<L/D≦30 (1)
where
L: a maximum length that extends from one end of the imaginary bisector line, which overlaps the corner of the mounting area, toward the outside of the mounting area while overlapping the imaginary bisector line and reaches an edge of the reinforcing wiring; and
D: a thickness of the reinforcing wiring.

4. The mounting board according to claim 1, wherein
where a protective film that covers at least the feed wiring on the mounting surface is defined as a first protective film, a protective film that covers at least the feed wiring on the non-mounting surface is defined as a second protective film, and
an imaginary bisector line is defined by extending a line bisecting an angle at the corner of the mounting area,
an area defined by a minimum distance between one end of the reinforcing wiring, which overlaps the imaginary bisector line, and one end of the second protective film, which overlaps the imaginary bisector line, is composed only of a main board as a base of the mounting board and the first protective film.

5. The mounting board according to claim 1, wherein
the reinforcing wiring extends out from the corner of the mounting area to an inside of the mounting area.

6. The mounting board according to claim 5, wherein
where one end in the mounting area, which overlaps a bump of the circuit element, is defined as an electrode superimposition point, and a group of a plurality of the electrode superimposition points is defined as an electrode superimposition point group,
an imaginary bisector line is defined by extending a line bisecting an angle at the corner of the mounting area, and
a line connecting, among outermost ones of the electrode superimposition points in the electrode superimposition point group, ones that sandwich the imaginary bisector line therebetween and are adjacent to each other at a minimum distance is defined as a boundary line,
the reinforcing wiring extends out from the corner of the mounting area toward the inside of the mounting area across the boundary line.

7. The mounting board according to claim 1, wherein
the reinforcing wiring functions also as the feed wiring.

8. The mounting board according to claim 1, wherein
an adhesive is interposed between the circuit element and the mounting area.

9. A mounting board set, comprising:
the mounting board according to claim 1; and
a circuit element mounted on the mounting board.

10. A mounting board set, comprising:
the mounting board according to claim 6; and
a circuit element mounted on the mounting board,
wherein
the bump included in the circuit element is connected to the feed wiring linked to the electrode superimposition point.

11. A panel unit, comprising:
the mounting board set according to claim 9; and
a liquid crystal display panel linked to the mounting board set.

12. A panel unit, comprising:
the mounting board set according to claim 10; and
a liquid crystal display panel linked to the mounting board set.

13. A mounting board set, comprising:
the mounting board according to claim 2; and
a circuit element mounted on the mounting board.

14. A mounting board set, comprising:
the mounting board according to claim 3; and
a circuit element mounted on the mounting board.

15. A mounting board set, comprising:
the mounting board according to claim 4; and
a circuit element mounted on the mounting board.

16. A mounting board set, comprising:
the mounting board according to claim 5; and
a circuit element mounted on the mounting board.

17. A mounting board set, comprising:
the mounting board according to claim 6; and
a circuit element mounted on the mounting board.

18. A mounting board set, comprising:
the mounting board according to claim 7; and
a circuit element mounted on the mounting board.

19. A mounting board set, comprising:
the mounting board according to claim 8; and
a circuit element mounted on the mounting board.
